(19) United States
(12) Patent Application Publication
(10) Pub. No.: US 2009/0314341 A1
(43) Pub. Date: Dec. 24, 2009

(54) SIMPLIFIED BACK CONTACT FOR POLYSILICON EMITTER SOLAR CELLS

(76) Inventors: Peter G. BORDEN, San Mateo, CA (US); Li Xu, Santa Clera, CA (US)

Correspondence Address: APPLIED MATERIALS;C/O PILLSBURY WINTHROP SHAW PITTMAN LLP, P .O . BOX 10500, MCLEAN, VA, 22120, US

(21) Appl. No.: 12/421,570

(22) Filed: Apr. 9, 2009

Related U.S. Application Data
(60) Provisional application No. 61/043,672, filed on Apr. 9, 2008.

(51) Int. Cl. H01L 31/02; H01L 21/20; H01L 21/302

(52) U.S. Cl. 136/256; 438/97; 438/98; 257/E21.09; 257/E21.214

(57) ABSTRACT

The present invention relates to forming contacts for solar cells. According to one aspect, an interdigitated back contact (IBC) cell design according to the invention requires only one patterning step to form the interdigitated junctions (vs. two for alternate designs). According to another aspect, the back contact structure includes a silicon nitride or a nitrided tunnel dielectric. This acts as a diffusion barrier, so that the properties of the tunnel dielectric can be maintained during a high temperature process step, and boron diffusion through the tunnel dielectric can be prevented. According to another aspect, the process for forming the back contacts requires no deep drive-in diffusions.

### CROSS REFERENCE TO RELATED APPLICATIONS

The present application claims priority to U.S. Prov. Appln. No. 61/043,672, filed Apr. 9, 2008, the contents of which are incorporated by reference herein in their entirety.

### FIELD OF THE INVENTION

The present invention relates to solar cells, and more particularly to all back contacts for polysilicon emitter solar cells.

### BACKGROUND

Interdigitated back contact solar cells are desirable in some applications because they offer high efficiency (>20%) and place the electrodes on the back surface, where they block no light. A commercial example of such a cell is the A300 cell offered by SunPower Corporation. This cell is expensive to make, as it requires a number of patterning steps and two diffusions to form the diffusions that create the n- and p-type regions on the back side. As used herein, the term back side or back surface refers to the conventional terminology of the solar cell surface opposite the surface receiving light for conversion to electric power by the solar cell.

Therefore, there is an interest in a process with fewer patterning and diffusion steps, especially if thermal steps can be done using rapid thermal processing rather than diffusion tubes. The diffusion tubes are less desirable because the thin cells readily break when loaded and unloaded, and the process is slow.

Some have considered using a polysilicon emitter (PE) structure to eliminate the deep diffusions. The PE cell was demonstrated in the early 1980s as a planar device, and there is some patent literature on it. For example, U.S. Patent Pub. No. 2006-0256728 describes a structure that requires two patterning steps to form n- and p-type doped layers, using a silicon dioxide tunnel oxide. Because silicon dioxide is not a barrier to boron diffusion, this structure can only use as-deposited layers, without high temperature firing. This is a disadvantage, as firing is often needed to reduce the sheet resistance of the polysilicon to acceptable levels.

Earlier devices include U.S. Pat. No. 5,057,439, which describes a structure similar to the aforementioned application, but which called for use of a high temperature step to punch through the silicon dioxide tunnel layer, therefore forming a conventional junction.

Accordingly, there remains a need in the art for a method for forming all back contacts for solar cells that overcome the problems of the prior art.

### SUMMARY

The present invention relates to contacts for solar cells and methods for making them. According to one aspect, an interdigitated back contact (IBC) cell design according to the invention requires only one patterning step to form the interdigitated junctions (as opposed to two for alternate designs). According to another aspect, the back contact structure includes a silicon nitride or a nitrided tunnel dielectric. This acts as a diffusion barrier, so that the properties of the tunnel dielectric can be maintained during a high temperature process step, and boron diffusion through the tunnel dielectric can be prevented. According to another aspect, the process for forming the back contacts requires no deep drive-in diffusions.

In furtherance of these and other aspects, a solar cell according to embodiments of the invention includes a substrate having a front surface and a back surface; a first contact structure to a first set of polysilicon regions formed on the back surface of the substrate; a second contact structure to a second set of polysilicon regions formed on the back surface of the substrate, the first and second polysilicon regions having opposite conductivity types; and a tunneling dielectric layer interposed between the first and second polysilicon regions and the substrate.

In additional furtherance of these and other aspects, a method of fabricating a solar cell according to embodiments of the invention includes preparing a substrate having a front surface and a back surface; depositing a first polysilicon layer on the back surface of the substrate; depositing a second polysilicon layer on the back surface of the substrate, the first and second polysilicon layers having opposite conductivity types; and performing an anneal that causes both the first and second deposited polysilicon layers to form respective first and second polysilicon regions on the back surface of the substrate.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIGS. 1A and 1B show two embodiments of a solar cell structure with back contacts according to the invention;

FIG. 1C illustrates a view of the metallization of the back side that can be accomplished in the embodiments of FIGS. 1A and 1B.

FIGS. 2A and 2B show a process flow for the structures of FIGS. 1A and 1B, respectively.

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Among other things, the present inventors recognize that the use of silicon nitride or a nitrided tunnel dielectric acts as a diffusion barrier, so that the properties of the tunnel dielectric can be maintained during a high temperature process step, and boron diffusion through the tunnel dielectric can be prevented. Examples of such techniques are described in co-pending U.S. Patent Appln. No. ______ (AM-13306), the contents of which are incorporated by reference herein in their entirety.

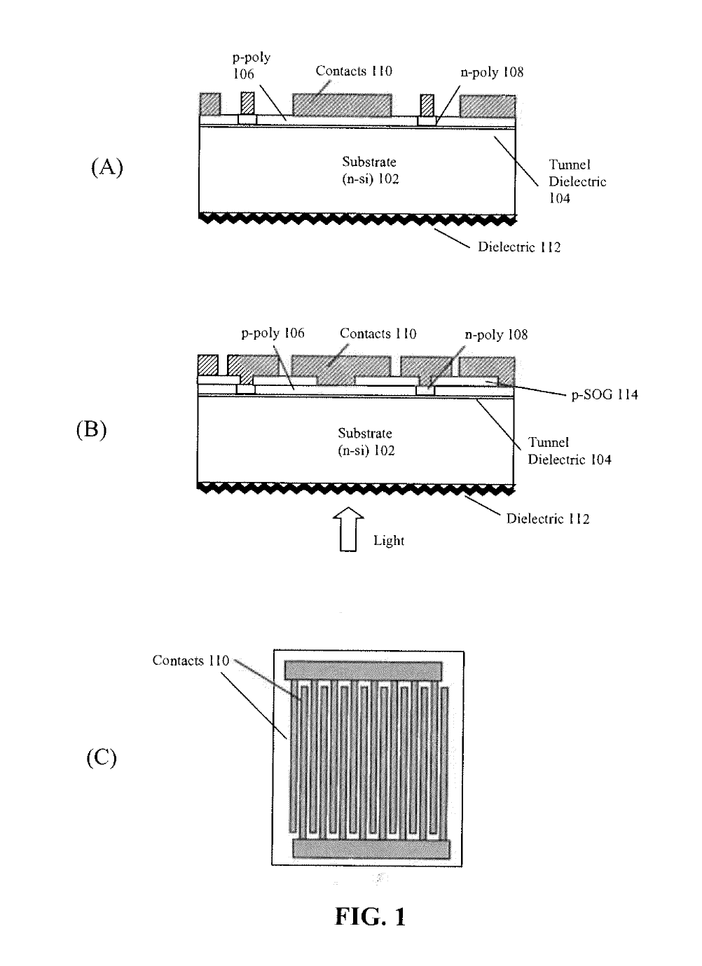

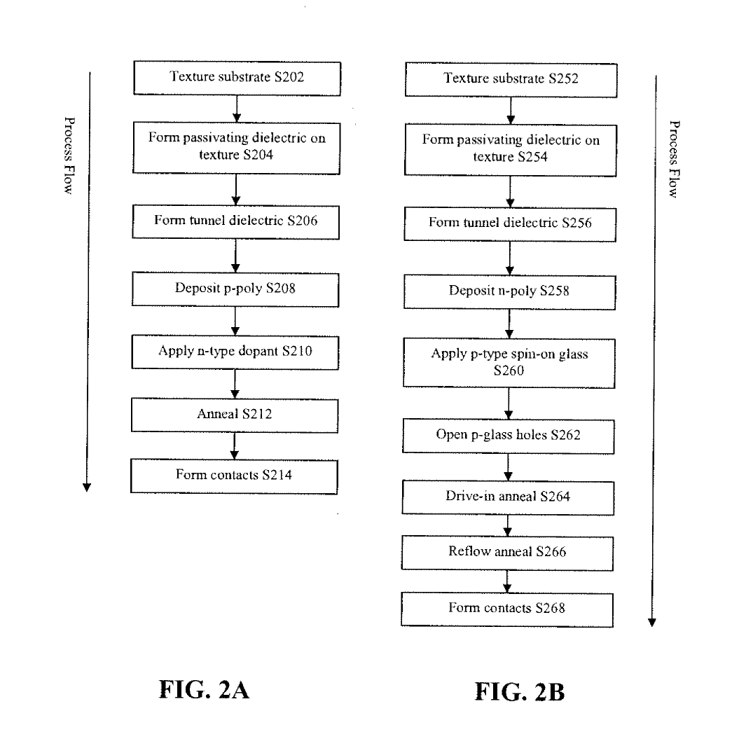

FIGS. 1A and 1B show two examples of a solar cell according to embodiments of the invention. The example of FIG. 1A is simpler, but requires a relatively narrow line width for the contact to the n-poly (assume substrate 102 is n-type silicon; for p-type substrates, the dopings are reversed). The process flow for this embodiment is shown in FIG, 2A. The embodiment of FIG. 1B has the same number of patterning steps, but uses an additional reflow anneal to enable use of a wider contact line. The process flow for this embodiment is shown in FIG. 2B.

FIG. 1C shows the back contact 110 lines from a top view of the back contact surface of the module, and illustrates how these lines 110 that connect to the n and p type poly are interdigitated. In this example, the contact lines 110 run longitudinally with respect to the longest dimension of the solar cell, and the n and p type contacts run parallel to each other and alternately. As further shown, the n and p type contact lines are both connected to common respective bus structures. Those skilled in the art will be familiar with such contact structures, and will understand how to implement them in connection with the present invention after being taught by the present disclosures. Moreover, the details of the structures of FIGS. 1A and 1B will become even further apparent from the process flow descriptions below.

Referring to the process flows in FIGS. 2A and 2B, in both embodiments, the front side of the cell is textured in step S202/S252 and a passivation dielectric coating 112 such as silicon dioxide or a tunnel oxide and polysilicon are applied in step S204/S254. Such passivation methods are well known in the art. An anti-reflection coating such as 78 nm of Si₃N₄ is typically then added (not shown).

Back side processing then begins. In the embodiment of FIG. 2A, a tunnel dielectric 104 is formed next in step S206. As it is desirable to block boron diffusion, this includes a nitrided layer, typically 8-12 Å thick. Many methods for making this layer can be used, for example methods for making such layers in making MOS IC's. A layer of p-type polysilicon 106 is then deposited in step S208. The doping of this layer is around 1-2×10¹⁹/cm³ of boron. The layer 106 is about 500-2000 Å thick. A n-type phosphorous doping paste such as phosphoric acid is then applied in lines, using screen printing or ink-jet, in step S210. The width of these regions must be less than the diffusion length of the minority carriers, which is on the order of 1 mm. A rapid thermal anneal, on the order of 1000° C. for 30 seconds is used in step S212 to drive in the phosphorous, forming n-type doped regions 108 interdigitated with the p-type doped regions 106. Contacts 110 may then be patterned and formed using conventional methods in step S214.

The process flow in the embodiment of FIG. 2B follows the flow of the embodiment of FIG. 2A in step S256, except the n-type poly 108 is deposited in step S258, using techniques similar to those in step S210, for example. A spin-on glass (SOG) 114 with boron dopant is then applied to the back surface in step S260. Holes are opened in the p-SOG in step S262; this defines regions 108 that will remain n-type. The SOG is annealed at 1000° C. for 30 seconds to drive in the boron, forming the p-doped region 106 in step S264. A second anneal at a lower temperature may optionally be used as shown in step S266 to flow the glass laterally so that it extends beyond the doped edge, to minimize shorting. In practice, this anneal is done in the same system as the first by lowering the temperature, Finally, contacts 110 are patterned and formed using conventional methods in step S268.

Although the present invention has been particularly described with reference to the preferred embodiments thereof, it should be readily apparent to those of ordinary skill in the art that changes and modifications in the form and details may be made without departing from the spirit and scope of the invention It is intended that the appended claims encompass such changes and modifications.

What is claimed is:

1. A solar cell comprising
a substrate having a front surface and a back surface;
a first contact structure to a first set of polysilicon regions formed on the back surface of the substrate;
a second contact structure to a second set of polysilicon regions formed on the back surface of the substrate, the first and second polysilicon regions having opposite conductivity types; and
a tunneling dielectric layer interposed between the first and second polysilicon regions and the substrate.

2. A solar cell as in claim 1, wherein the tunneling dielectric layer includes a nitride layer.

3. A solar cell as in claim 1, wherein the first and second contact structures are interdigitated with respect to each other.

4. A solar cell as in claim 1, further comprising a passivating dielectric formed on the front surface of the substrate.

5. A method of fabricating a solar cell comprising:
preparing a substrate having a front surface and a back surface;
depositing a first polysilicon layer on the back surface of the substrate;
depositing a second polysilicon layer on the back surface of the substrate, the first and second polysilicon layers having opposite conductivity types; and
performing an anneal that causes both the first and second deposited polysilicon layers to form respective first and second polysilicon regions on the back surface of the substrate.

6. A method according to claim 5, further comprising:
forming a tunneling dielectric layer interposed between the first and second polysilicon regions and the substrate before performing the anneal step, wherein the tunneling dielectric layer is comprised of material that blocks diffusion from the polysilicon regions to the substrate.

7. A method according to claim 6, wherein the tunneling dielectric layer includes a nitride layer.

8. A method according to claim 5, wherein the step of depositing the first polysilicon layer includes depositing a thin layer of p-type polysilicon material on the back surface, and wherein the step of depositing the second polysilicon layer includes patterning lines of n-type polysilicon material on the first polysilicon layer.

9. A method according to claim 5, wherein the step of depositing the first polysilicon layer includes patterning lines of n-type polysilicon material on the back surface, and wherein the step of depositing the second polysilicon layer includes depositing a layer of p-type polysilicon material over the back surface and the first polysilicon layer, and opening holes in the second polysilicon layer to expose the first polysilicon layer.

10. A method according to claim 9, wherein the p-type polysilicon material comprises a spin-on glass (SOG).

11. A method according to claim 9, wherein the anneal step includes a drive-in anneal followed by a reflow anneal.

12. A method according to claim 11, wherein both the drive-in anneal and the reflow anneal are performed using the same anneal.

13. A method according to claim 5, further comprising:
forming first and second contact structures respectively contacting to the first and second polysilicon regions.

14. A method according to claim 13, wherein the first and second contact structures are formed so as to be interdigitated with respect to each other.

15. A method according to claim 5, further comprising forming a passivating dielectric on the front surface of the substrate.
